(19) United States
(12) Patent Application Publication
(10) Pub. No.: US 2026/0040538 A1
(43) Pub. Date: Feb. 5, 2026

(54) ONE-TIME PROGRAMMABLE MEMORY CELL

(71) Applicant: SEMICONDUCTOR COMPONENTS INDUSTRIES, LLC, Scottsdale, AZ (US)

(72) Inventors: Gang LIU, Camas, WA (US); Santosh MENON, Portland, OR (US)

(73) Assignee: SEMICONDUCTOR COMPONENTS INDUSTRIES, LLC, Scottsdale, AZ (US)

(21) Appl. No.: 19/036,731

(22) Filed: Jan. 24, 2025

Related U.S. Application Data
(60) Provisional application No. 63/678,705, filed on Aug. 2, 2024.

(51) Int. Cl. H10B 20/25; G11C 17/16; G11C 17/18

(52) U.S. Cl. CPC H10B 20/25; G11C 17/16; G11C 17/18

(57) ABSTRACT

A memory cell is disclosed. The memory cell comprises a transistor. The transistor includes a gate, a drain region coupled to a drain terminal by one or more drain contacts, and a source region coupled to a source terminal by a source contact. A cumulative drain-contact area of the one or more drain contacts of the transistor is greater than a source-contact area of the transistor. Further a source-contact silicide is located between the source contact and the source region, and the source-contact silicide is configured to migrate into the source region in response to a programming current conducted through the drain region and the source region.

This application claims the benefit of provisional patent application No. 63/678,705, filed Aug. 2, 2024, which is hereby incorporated by reference herein in its entirety.

### TECHNICAL FIELD

The disclosure relates generally to integrated circuit technology, and particularly to one-time programmable (OTP) memories.

### BACKGROUND

Programmable read-only memories (PROMs) may have individual cells with one or both of a fuse and an antifuse. The triggering of the fuse or the antifuse after manufacturing may permanently set the bit of the cell as a logic-one or a logic-zero in a process known as one-time programming. An antifuse may be implemented with a silicon metal-oxide semiconductor field-effect transistor (MOSFET or MOS transistor). During programming, the gate and the source of the MOSFET may be shorted together by an avalanche breakdown across the gate oxide upon the application of a high voltage from the gate to the source of the MOSFET. Further, an electrically programmed fuse bit cell may include a fuse and a control transistor. The fuse may be programmed by destructively blowing apart, or simply increasing the resistance, of a strip of metal or polymeric material with a high-density current by way of a large input to output voltage across the strip.

The inventors of embodiments of the present disclosure have recognized that conventional techniques relying on the breakdown of either a gate oxide of a transistor or a strip of metal or polymeric material may reduce the reliability of a PROM. The inventors of embodiments of the present disclosure have also recognized that high-current densities for programming a fuse require a large control transistor size, thereby significantly contributing to the size and cost of the bit cell. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1A illustrates a top view of semiconductor process areas for a transistor in accordance with embodiments of the present disclosure.

FIG. 1B illustrates a top view of semiconductor process areas for a transistor in accordance with embodiments of the present disclosure.

FIG. 2A illustrates a cross-section view of a transistor in accordance with embodiments of the present disclosure.

FIG. 2B illustrates a cross-section view of a transistor in accordance with embodiments of the present disclosure.

FIG. 2C illustrates a cross-section view of a transistor in accordance with embodiments of the present disclosure.

FIG. 3 illustrates waveforms showing the pre-programming and post-programming drain-current linearity of a transistor in accordance with embodiments of the present disclosure.

FIG. 4A illustrates schematic diagram of a memory array in accordance with embodiments of the present disclosure.

FIG. 4B is a chart illustrating operating conditions of a memory array in accordance with embodiments of the present disclosure.

FIG. 5 illustrates an example method of operating a one-time programmable (OTP) memory cell in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to mean either an indirect or direct connection. Thus, if a first device couples to, or is coupled to, a second device, that connection between the first device and the second device may be through a direct connection or through an indirect connection via other devices and connections.

The embodiments described herein disclose a memory cell. The memory cell may be a one-time programmable (OTP) memory cell. In some embodiments, the memory cell may be formed by a single transistor, and may thus be referred to as an single-transistor memory cell or a single-transistor OTP memory cell. As described herein, programming the memory cell may increase the source resistance of the transistor within the memory cell. Thus, the memory cell may also be referred to as an OTP fuse, and the single transistor within the memory cell may also be referred to as a single-transistor fuse. As described in detail below, the memory cell may be programmed by conducting an over-stress current through the drain and the source of the transistor. The transistor may be configured such that, in response to the conducted current, source-contact silicide migration occurs in the source region, thereby increasing the source resistance and resulting in lower conduction current under given operating conditions. By configuring the transistor to be programmed by a source-contact silicide migration, an OTP memory cell may be implemented with Complementary Metal-Oxide Semiconductor (CMOS) processing steps, a single gate oxide, a small footprint, and good reliability.

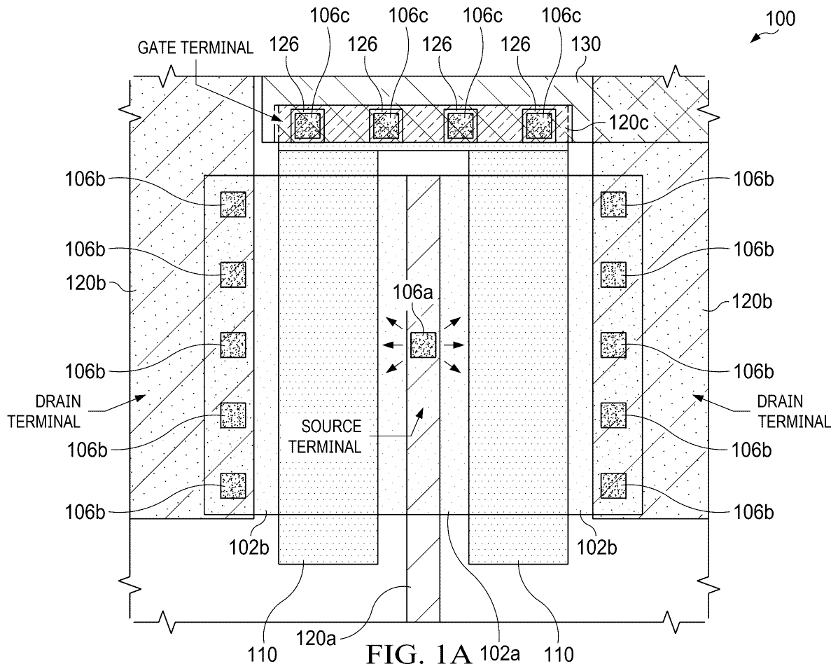

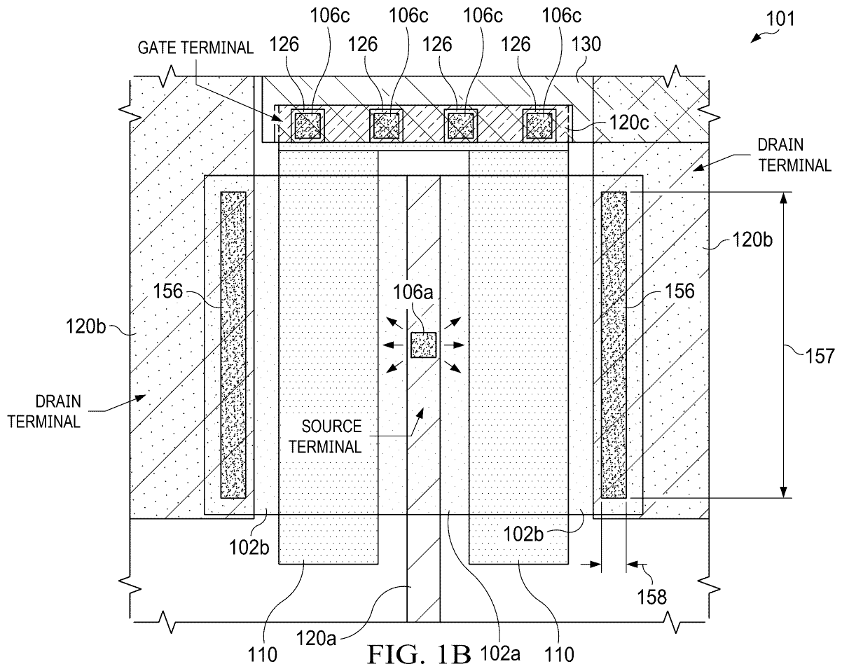

FIG. 1A illustrates a top view of semiconductor process areas for transistor 100 in accordance with embodiments of the present disclosure. In some embodiments, transistor 100 may be an n-type metal-oxide-semiconductor field-effect transistor (n-type MOSFET or NMOS transistor). As shown in FIG. 1A, the semiconductor process areas may include active areas 102a and 102b, polysilicon areas 110, contact areas 106a, 106b, and 106c, first metal layer areas 120a, 120b, 120c, vias 126, and second metal layer area 130.

Polysilicon areas 110 may be utilized to form the gate of transistor 100. The polysilicon areas 110 forming the gate of transistor 100 may be coupled to a gate terminal of transistor 100 by various contact, via, and metal routing layers. For example, as shown in FIG. 1A, contact areas 106c may be used to form gate contacts that may couple polysilicon areas 110 up to first metal layer area 120c, and vias 126 may couple first metal layer area 120c to second metal layer area 130.

The active areas to either side of polysilicon areas 110 may form the source region and the drain region of transistor 100. Active area 102a may form the source region of transistor 100. The source region may be coupled to a source terminal of transistor 100 by a source contact. In some embodiments, the source region may be coupled to a source terminal of transistor 100 by a single source contact. For example, contact area 106a may be utilized to form a single source contact that may couple the underlying source region to above metal routing layers, such as first metal layer area 120a, which may form and/or be coupled to the source terminal of transistor 100. Further, active areas 102b may form the drain region of transistor 100. The drain region may be coupled to a drain terminal of transistor 100 may one or more drain contacts. For example, contact areas 106b may be utilized to form drain contacts that may couple the underlying drain region to above metal routing layers, such as first metal layer area 120b, which may form and/or be coupled to the drain terminal of transistor 100.

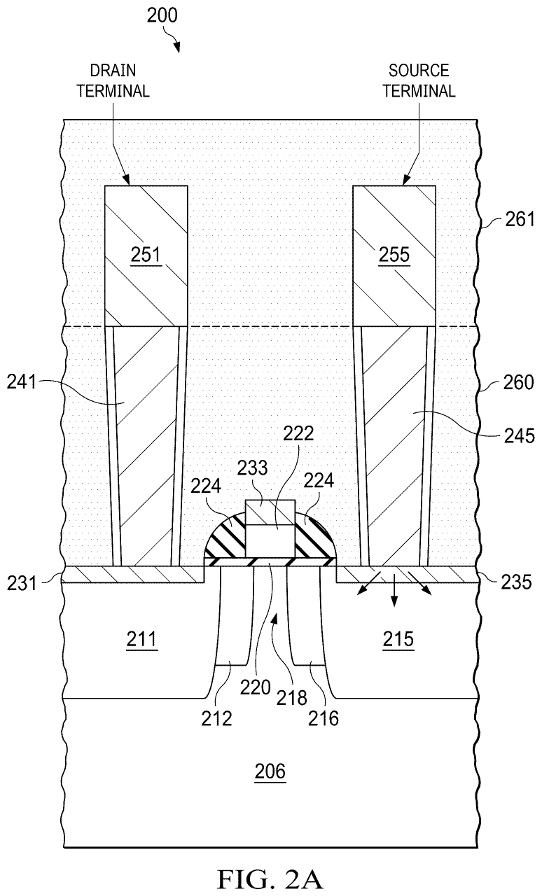

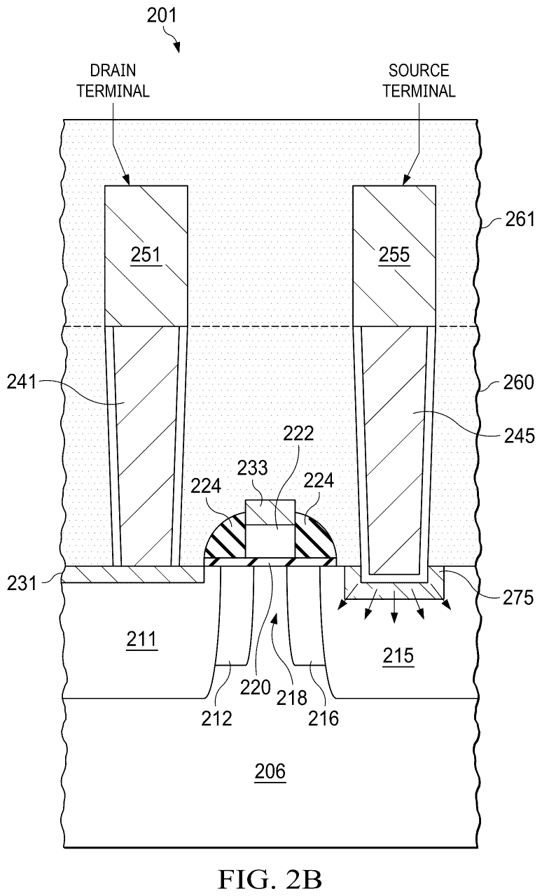

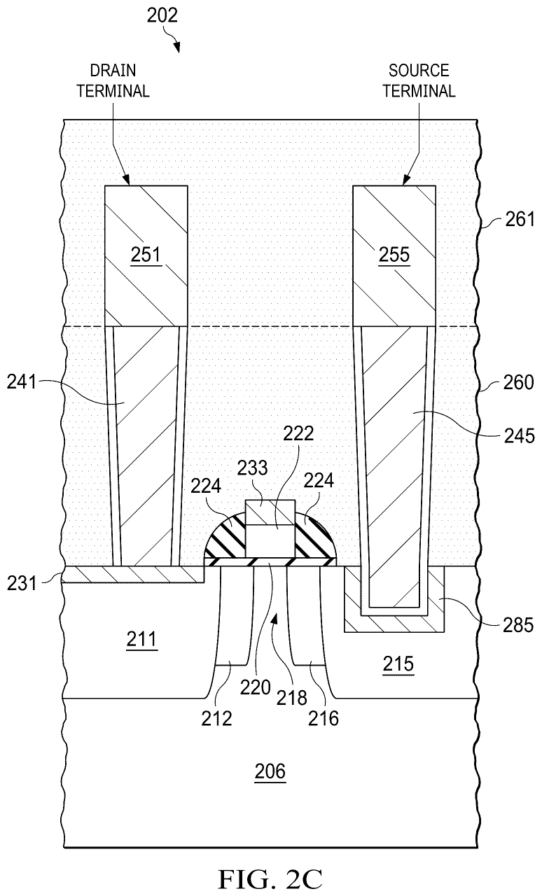

As described in further detail below with reference to the cross-sectional views of FIGS. 2A through 2C, a silicide may be located between the various gate, source, and drain contacts and their underlying regions. Specifically, a source-contact silicide may be locate between the source contact and the underlying source region of transistor 100, a drain-contact silicide may be located between each of the one or more drain contacts and the underlying drain region, and a gate silicide may be located between the gate contact and the polysilicon gate. Such silicide may be used during semiconductor processing to improve the electrical conductivity of contacts to underlying regions.

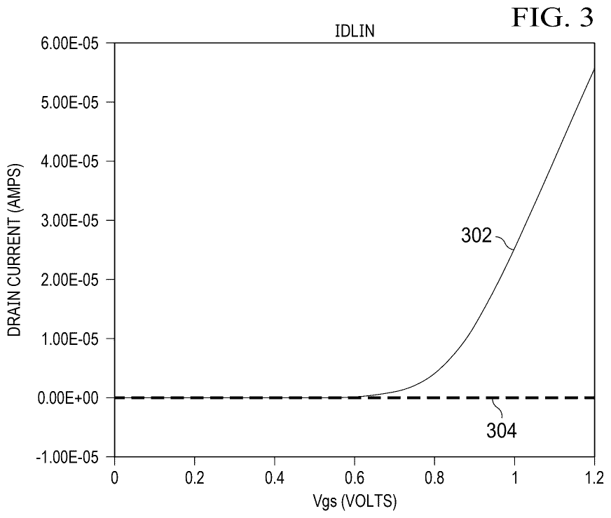

In some embodiments, transistor 100 may be configured such that the source-contact silicide located between the source contact and the source region is configured to migrate into the source region in response to a programming current conducted through the drain region and the source region of transistor 100. For example, a programming current conducted from the drain terminal to the source terminal of transistor 100 may cause an electron flux to flow out of the source contact formed by contact area 106a in FIG. 1A and into the source region formed by active area 102a. The electron flux may cause the source-contact silicide, located at the border between the source contact and the source region, to migrate into the source region and away from the source contact. The migration of the source-contact silicide may in turn reduce the electrical conductivity between the source contact and the underlying source region, thereby increasing the source resistance of transistor 100. And as described in further detail below with reference to FIG. 3, this increased source resistance can be read and thus utilized for a one-time programmable memory.

In some embodiments, the programming current described directly above may be provided by applying a voltage outside of the safe-operating area of the transistor. For example, in an embodiment where transistor 100 is an NMOS transistor implemented with a 1.2 volt CMOS process, the safe operating area of transistor 100 may be between zero and 1.32 volts and the drain-to-source breakdown voltage (BVDSS) may be 8 volts. To program transistor 100, the gate of transistor 100 may be biased above the gate-to-source threshold of transistor 100 to place transistor 100 in an on-state, and a voltage may be applied from the drain to the source of transistor 100 that is greater than the safe-operating voltage of 1.32 volts of transistor 100. As a programming current is conducted in response to the voltage applied across the drain and source of transistor 100, the source-contact silicide may migrate as described directly above, thereby causing the source resistance of transistor 100 to increase. The increased source resistance may in turn reduce the programming current conducted in response to the voltage applied across the drain and the source of transistor 100. In some embodiments, the voltage and/or the resulting programming current may be applied as a pulse for a predetermined period of time. In other embodiments, the programming may be stopped when the programming current drops below a programming-complete threshold indicating that the source-resistance of transistor has been increased by at least a detectable margin.

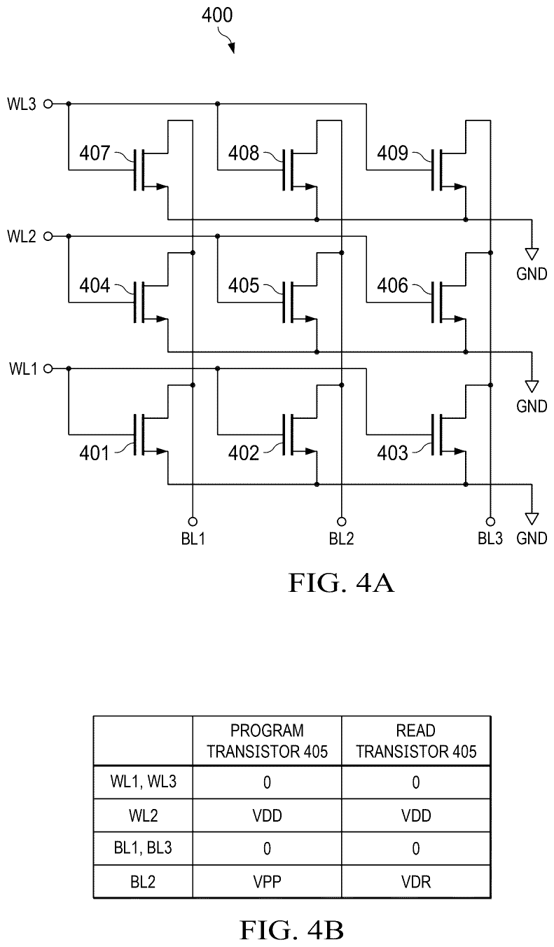

In some embodiments, the voltage applied across the drain and the source of transistor 100 to program transistor 100 may be greater than the safe-operating voltage of transistor 100, but less than the BVDSS of transistor 100. For example, as described in further detail below with reference to FIG. 4A and FIG. 4B, the memory cell formed by transistor 100 may be part of a memory array. In such a memory array, multiple instances of transistor 100 included in the different memory cells of the memory array may have shared gate connections or shared drain connections with each other. The voltage applied across the drain to source of any given instance of transistor 100 during programming of that transistor, may be kept less than the BVDSS. Accordingly, the programming process for one instance of transistor 100 may avoid damaging other instances of transistor 100 in the same memory array with shared drain connections.

As shown in FIG. 1A, the gate formed by polysilicon areas 110 may include two fingers. Thus, transistor 100 may be a two-finger MOSFET. Although the example embodiment of transistor 100 is shown in FIG. 1A as a two-finger MOSFET, transistor 100 may be implemented with one, two, four, or any suitable number of fingers. For example, in other embodiments, transistor 100 may be formed by a single finger, with a single contiguous drain region located on an opposite side of a single gate finger relative to the source region. In other embodiments, transistor 100 may take any other suitable shape, such as a circular or a hexagon shape, with the source region located in the middle of a circular or hexagonal gate area and the drain region located outside of the circular or hexagonal gate area.

In some embodiments, the cumulative drain-contact area of the one or more drain contacts of transistor 100 may be greater than the source-contact area of transistor 100. For example, as shown in the example embodiment of FIG. 1A, a single contact area 106a may be used to form the source contact and multiple contact areas 106b may be utilized to form the drain contacts. The cumulative area of the contact areas 106b utilized to form the drain contacts may thus be larger than the area of the single contact area 106a utilized to form the source contact. In some embodiments, the cumulative drain-contact area may be greater and the source contact area by a ratio of at least 2:1, 5:1, 10:1, or more. By making the cumulative drain-contact area greater than the source-contact area, the cumulative drain-contact area may have a lower current density than the source-contact area. Thus, the desired source-contact silicide migration may be induced by the programming current as described above, while also limiting or avoiding unwanted drain-contact silicide migration at the one or more drain contacts. By increasing the cumulative drain-contact area, and thereby limiting the impact that the programming current may have on the drain contact, the reliability of transistor 100 under the over-stress conditions of the programming may be improved. As described in further detail below with reference to FIG. 1B, the cumulative drain-contact area may also be increased by utilizing a drain contact bar. For example, the one or more drain contacts of a transistor may include and/or may be implemented by one or more drain-contact bars.

FIG. 1B illustrates a top view of semiconductor process areas for transistor 101 in accordance with embodiments of the present disclosure. Transistor 101 shown in FIG. 1B may represent an alternative embodiment of transistor 100 shown in FIG. 1A. Transistor 101 may include similar features as transistor 100, but may additionally include one or more drain-contact bars 156 to couple the underlying drain region to above metal routing layers, such as first metal layer area 120b, which may form and/or be coupled to the drain terminal of transistor 101. Drain-contact bars 156 may have a width 158 and a length 157. As shown in FIG. 1B, the length 157 may be greater than the width 158. In some embodiments, the length 157 may be greater than the width 158 by a ratio of at least 2:1, 5:1, 10:1, or more. By utilizing one or more drain-contact bars 156 in place of, or in addition to, the drain contacts formed by contact areas 106b shown in FIG. 1A, the cumulative drain-contact area of transistor 101 may be further increased.

FIG. 2A illustrates a cross-section view of transistor 200 in accordance with embodiments of the present disclosure. Transistor 200 may represent an embodiment of transistor 100 described above with reference to FIG. 1A. As shown in FIG. 2A, transistor 200 may include well region 206, drain region 211, low-doped region 212, channel region 218, low-doped region 216, source region 215, gate oxide 220, gate 222, and spacers 224. As described in further detail below, transistor 200 may also include various silicide and contact layers to couple drain region 211, source region 215, and gate 222 to above metal routing and the respective drain, source, and gate terminals.

Transistor 200 may be formed in well region 206. In embodiments where transistor 200 is an NMOS transistor, well region 206 may be a p-type well. Doping of the opposite conductivity type relative to well region 206 may be added to well region 206 to form the source and the drain of transistor 200. For example, utilizing the polysilicon of gate 222 as a mask, a low n-type doping level may be applied to form low-doped regions 212 and 216. After subsequent formation of spacers 224, a heavy n-type doping level may be applied to form drain region 211 and source region 215. As shown in FIG. 2A, gate oxide 220 may be located below gate 222 and may abut the upper surface of well region 206. Channel region 218 may thus be located in well region 206 under gate oxide 220 and between the low-doped regions 212 and 216 adjacent to drain region 211 and source region 215 respectively.

During semiconductor processing of transistor 200, and after doping is applied to form drain region 211 and source region 215, heat may be applied to provide a source and drain (SD) annealing. A silicide may then be formed over active areas of transistor 200. A metal film, including one or more of nickel, titanium, and/or tungsten, for example, may be deposited over the active areas of transistor 200. The metal film may react with the underlying polysilicon and/or active areas to form silicide. For example, drain-contact silicide 231 may form on an upper surface of drain region 211. Further, source-contact silicide 235 may form on an upper surface of source region 215. In addition, gate silicide 233 may form on an upper surface of the polysilicon of gate 222.

After silicide formation, a thin silicon nitride (SiN) passivation layer may be deposited, and an interlayer dielectric (ILD) 260 may be formed over the passivation layer and the active areas of transistor 200. The SiN passivation layer may serve as an etch stop layer for layer etching steps, described below, that etch oxide at a faster rate than SiN. In some embodiments, ILD 260 may be formed by silicon dioxide, or any other suitable dielectric material. A chemical mechanical polishing (CMP) may then be performed to planarize and smooth an upper surface of ILD 260. A contact mask (CA mask) may then be applied to provide a contact etch through ILD 260. The contact etch through ILD 260 may provide the holes through which the contacts for each of the drain, source, and gate, may be formed.

After formation of the holes through ILD 260, a contact-liner layer including at least one of titanium and/or titanium nitride (Ti/TiN) may be deposited. A rapid thermal anneal (RTN) may then be applied, providing a high temperature at which the titanium may react with underlying silicon to form silicide. A metal material, such as tungsten (W), may then be deposited in to the holes to form contacts for the drain, source, and gate. For example, as shown FIG. 2A, drain contact 241 may be formed above drain region 211 and drain-contact silicide 231. Further, source contact 245 may be formed above source region 215 and source-contact silicide 235. Although not visible from the cross-section view of FIG. 2A, transistor 200 may include a gate contact that couples gate 222 and gate silicide 233 to the gate terminal on upper metal routing layers, similar to transistor 100 shown in the top view of FIG. 1A. Moreover, although not visible from the cross-section view of FIG. 2A, transistor 200 may include additional drain contacts that may providing additional couplings between drain region 211 and drain terminal 251, similar to the multiple drain contacts of transistor 100 shown in the top view of FIG. 1A.

After the metal material, such as tungsten (W), has been deposited to form the contacts for the drain, source, and gate, an additional chemical mechanical polishing (CMP) may be performed to again planarize the upper surface of ILD 260, as well as the upper surface of the respective gate, drain, and source contacts. Further dielectric layers, such as interlayer dielectric (ILD) 261, and further metal layers, may then be layered above ILD 260. For example, similar to the description above for transistor 100 in FIG. 1A, a drain terminal 251 and source terminal 255 may be formed by, at least in part, patterns of a first metal layer coupled to the respective drain contact 241 and source contact 245.

In the embodiment shown in FIG. 2A, transistor 200 may be implemented as a single-finger MOSFET, with a single gate 222, and a single drain region 211 and a single source region 215. In other embodiments, transistor 200 may be a multi-finger MOSFET, with for example a source region located between two gate fingers and drain regions on opposing sides of the respective gate fingers from the source region similar to the illustration for transistor 100 in FIG. 1A.

As described above with reference to FIG. 1A, during programming of a transistor such as transistor 200, a programming current may be induced from the drain to the source of transistor 200. According to the programming current, electrons may flow in the direction from the source contact 245, through source-contact silicide 235 and source region 215, through low-doped region 216, channel region 218, and low-doped region 212, and to drain region 211. As shown in FIG. 2A, the source contact 245 and source-contact silicide 235 may abut an upper surface of source region 215. The electron flux may cause source-contact silicide 235 to migrate into source region 215 and away from source contact 245. The migration of source-contact silicide 235 may in turn reduce the electrical conductivity between source contact 245 and the underlying source region 215, thereby increasing the source resistance of transistor 200. And as described in further detail below with reference to FIG. 3, this increased source resistance can be read and thus utilized for an OTP memory cell. Accordingly, an OTP memory cell may be achieved without adding additional semiconductor processing layers or masking steps to a CMOS process as described above.

FIG. 2B illustrates a cross-section view of transistor 201 in accordance with embodiments of the present disclosure. Transistor 201 may represent an alternate embodiment of transistor 200 described above with reference to FIG. 2A. For example, transistor 201 may be formed with a majority of similar semiconductor processing steps as described above for transistor 200, and may thus include similar elements including well region 206, drain region 211, low-doped region 212, channel region 218, low-doped region 216, source region 215, gate oxide 220, gate 222, and spacers 224, as well as drain-contact silicide 231, gate silicide 233, drain contact 241, source contact 245, ILD 260, ILD 261, drain terminal 251, and source terminal 255.

During the semiconductor processing of transistor 201, a silicide block mask may be applied over source region 215 during the initial silicide formation occurring after the source and drain (SD) annealing. Accordingly, the source-contact silicide 235 illustrated in FIG. 2A may be omitted from transistor 201 as illustrated in FIG. 2B.

As described above with reference to FIG. 2A, after ILD 260 is formed, a contact mask (CA mask) may then be applied to provide a contact etch through ILD 260. The contact etch through ILD 260 may provide the holes through ILD 260 through which the contacts for each of the drain, source, and gate, may be formed. The contact etch may react more quickly with silicon than, for example, a silicide layer. In some embodiments, the contact etch may thus create a recess in the upper surface of source region 215. Thus, as shown in FIG. 2B, the hole through which source contact 245 is later formed may extend into source region 215. As also described above with reference to FIG. 2A, after formation of the holes through ILD 260, a contact-liner layer including at least one of titanium and/or titanium nitride (Ti/TiN) may be deposited. A rapid thermal anneal (RTN) may then be applied, providing a high temperature at which the titanium may react with underlying silicon to form silicide. The contact-liner layer may line the bottom and the inner walls of the holes through ILD 260 used to create the respective gate, drain, and source contacts. At the bottom of the hole to be used to form the source contact, the titanium and/or titanium nitride may react with the silicon along the recess in the upper surface of source region 215 to produce a TiSiₓ silicide that may form source-contact silicide 275. A metal material, such as tungsten (W), may then be deposited in to the holes to form contacts for the drain, source, and gate. For example, as shown FIG. 2B, drain contact 241 may be formed above drain region 211 and drain-contact silicide 231. Further, source contact 245 may be formed above source region 215 and source-contact silicide 275. Although not visible from the cross-section view of FIG. 2B, transistor 201 may include a gate contact that may couple gate 222 and gate silicide 233 to the gate terminal on upper metal routing layers, similar to transistor 100 shown in the top view of FIG. 1A. Moreover, although not visible from the cross-section view of FIG. 2B, transistor 201 may include additional drain contacts that may couple drain region 211 to drain terminal 251, similar to transistor 100 shown in the top view of FIG. 1A.

As described above with reference to FIG. 1A, during programming of a transistor such as transistor 201, a programming current may be induced from the drain to the source of transistor 201. According to the programming current, electrons may flow in the direction from the source contact 245, through source-contact silicide 275 and source region 215, through low-doped region 216, channel region 218, and low-doped region 212, and to drain region 211. As shown in FIG. 2B, source contact 245 and source-contact silicide 275 may extend into a recess in a surface of source region 215. The electron flux may cause source-contact silicide 275 to migrate into source region 215 and away from source contact 245. The migration of source-contact silicide 275 may in turn reduce the electrical conductivity between source contact 245 and the underlying source region 215, thereby increasing the source resistance of transistor 201. And as described in further detail below with reference to FIG. 3, this increased source resistance can be read and thus utilized for an OTP memory cell.

Forming source-contact silicide 275 in a recess within source region 215 may aid the migration process by providing more surface contact area between source-contact silicide 275 and source region 215. Formation of the source-contact silicide 275 in a recess may thus improve the reliability and the programmability of transistor 201 across semiconductor process variations for a given set of programming conditions. Moreover, such improvement may be achieved without adding additional semiconductor processing layers or masking steps to a CMOS process as described above.

FIG. 2C illustrates a cross-section view of transistor 202 in accordance with embodiments of the present disclosure. Transistor 202 may represent an alternate embodiment of transistor 200 described above with reference to FIG. 2A and an alternate embodiment of transistor 201 described above with reference to FIG. 2B. For example, transistor 202 may be formed with a majority of similar semiconductor processing steps as described above for transistor 200 and transistor 201, and may thus include similar elements including well region 206, drain region 211, low-doped region 212, channel region 218, low-doped region 216, source region 215, gate oxide 220, gate 222, and spacers 224, as well as drain-contact silicide 231, gate silicide 233, drain contact 241, source contact 245, ILD 260, ILD 261, drain terminal 251, and source terminal 255.

Similar to the description above for transistor 201 in FIG. 2B, a silicide block mask may be applied over source region 215 during the initial silicide formation occurring after the source and drain (SD) annealing. Accordingly, the source-contact silicide 235 illustrated in FIG. 2A may be omitted from transistor 202 as illustrated in FIG. 2C.

As described above with reference to FIG. 2B, after ILD 260 is formed, a contact mask (CA mask) may then be applied to provide a contact etch through ILD 260. The contact etch through ILD 260 may provide the holes through which the contacts for each of the drain, source, and gate, may be formed. The contact etch may react more quickly with silicon than, for example, a silicide layer. In some embodiments, the contact etch may thus create a recess in the upper surface of source region 215. Moreover, an additional contact mask, specific to the source contact, and silicon etch, may be applied to create a deep recess in the silicon of source region 215. Thus, as shown in FIG. 2C, the hole through which source contact 245 is later formed may extend deep into source region 215. As also described above with reference to FIG. 2B, after formation of the holes through ILD 260, a contact-liner layer including at least one of titanium and/or titanium nitride (Ti/TiN) may be deposited. A rapid thermal anneal (RTN) may then be applied, providing a high temperature at which the titanium may react with underlying silicon to form a silicide. The contact-liner layer may line the bottom and the inner walls of the holes through ILD 260 used to create the respective gate, drain, and source contacts. At the bottom of the hole to be used to form the source contact, the titanium and/or titanium nitride may react with the silicon along the recess in the upper surface of source region 215 to produce a TiSiₓ silicide that may form source-contact silicide 285. A metal material, such as tungsten (W), may then be deposited in to the holes to form contacts for the drain, source, and gate. For example, as shown FIG. 2C, drain contact 241 may be formed above drain region 211 and drain-contact silicide 231. Further, source contact 245 may be formed above source region 215 and source-contact silicide 285. Although not visible from the cross-section view of FIG. 2C, transistor 202 may include a gate contact that couples gate 222 and gate silicide 233 to the gate terminal on upper metal routing layers, similar to transistor 100 shown in the top view of FIG. 1A. Moreover, although not visible from the cross-section view of FIG. 2C, transistor 202 may include additional drain contacts that may couple drain region 211 to drain terminal 251, similar to transistor 100 shown in the top view of FIG. 1A.

As described above with reference to FIG. 1A, during programming of a transistor such as transistor 202, a programming current may be induced from the drain to the source of transistor 202. According to the programming current, electrons may flow in the direction from the source contact 245, through source-contact silicide 285 and source region 215, through low-doped region 216, channel region 218, and low-doped region 212, and to drain region 211. As shown in FIG. 2C, source contact 245 and source-contact silicide 285 may extend into a recess in a surface of source region 215. The electron flux may cause source-contact silicide 285 to migrate into source region 215 and away from source contact 245. The migration of source-contact silicide 285 may in turn reduce the electrical conductivity between source contact 245 and the underlying source region 215, thereby increasing the source resistance of transistor 202. And as described in further detail below with reference to FIG. 3, this increased source resistance can be read and thus utilized for an OTP memory cell.

Forming source-contact silicide 285 in a deep recess within source region 215 may aid the migration process by providing more surface contact area between source-contact silicide 285 and source region 215. Formation of the source-contact silicide 285 in a deep recess may thus improve the reliability and the programmability of transistor 202 across semiconductor process variations for a given set of programming conditions. Moreover, such improvement may be achieved by adding a single source-contact specific mask and etching step to a CMOS process as described above.

FIG. 3 illustrates waveforms showing the pre-programming and post-programming drain-current linearity of a transistor in accordance with embodiments of the present disclosure. For example, plot 302 illustrates the pre-programming drain current linearity (IDLIN) of a transistor, such as transistor 100, transistor 101, transistor 200, transistor 201, or transistor 202 described above. Further, plot 304 illustrates the post-programming drain current linearity (IDLIN) of a transistor, such as transistor 100, transistor 101, transistor 200, transistor 201, or transistor 202 described above.

As described above with reference to FIGS. 1A-1B and 2A-2C, an OTP memory cell may include a single transistor. During programming, a programming current may be conducted through the transistor from the drain to the source that may cause a source-contact silicide migration, thereby increasing the source resistance of the transistor. The increased source resistance may change the drain current linearity of the transistor as illustrated in FIG. 3.

FIG. 3 plots the drain current of the transistor under conditions where the gate-to-source voltage is swept from 0 to 1.2 volts, and a read-level voltage of, for example, 100 millivolts is applied across the drain and the source of the transistor. As shown by plot 302, prior to programming, the drain current may increase exponentially as Vgs increases above the gate-to-source threshold of the transistor at around 0.7 volts. During programming, the source resistance of the transistor may be increased. The increased source resistance not only places a resistance in the conduction path of the transistor, but also attenuates the effect that the gate-to-source voltage of the transistor would otherwise have to open the conduction channel of the transistor. Thus, as shown by plot 304, the increased source resistance of the transistor post-programming may limit the drain current to a near zero or negligible amount relative to the pre-programming drain current.

FIG. 4A illustrates a schematic diagram of a memory array 400 in accordance with embodiments of the present disclosure. Memory array 400 may comprise a plurality of memory cells, each of which may comprise a transistor. In some embodiments, each memory cell may include, or be formed by, a single transistor. For example, each of transistors 401, 402, 403, 404, 405, 406, 407, 408, and 409 shown in FIG. 4A may form an individual memory cell. In some embodiments, each of transistors 401, 402, 403, 404, 405, 406, 407, 408, and 409 may be implemented as NMOS transistors.

In some embodiments, memory array 400 may include a plurality of memory cells arranged in one or more rows and one or more columns. For example, as shown in FIG. 4A, transistors 401, 402, and 403 may form a first row, and may each have a gate driven by a first word line (WL1). Transistors 404, 405, and 406 may form a second row, and may each have a gate driven by a second word line (WL2). Further, transistors 407, 408, and 409 may form a third row, and may each have a gate driven by a third word line (WL3). In addition, transistors 401, 404, and 407 may form a first column, and may each have a drain coupled to a first bit line (BL1). Transistors 402, 405, and 408 may form a second column, and may each have a drain coupled to a second bit line (BL2). Further, transistors 403, 406, and 409 may form a third column, and may each have a drain coupled to a third bit line (BL3). The respective sources of each of transistors 401, 402, 403, 404, 405, 406, 407, 408, and 408, may be coupled to ground GND. Although a 3×3 memory array is described herein and shown in FIG. 4A for illustration purposes, memory array 400 may be formed with any suitable number of rows and/or any suitable number of columns to provide the number of bits of memory required for a given application.

Each of transistors 401, 402, 403, 404, 405, 406, 407, 408, and 409 may represent an instance of an embodiment of transistor 100, transistor 101, transistor 200, transistor 201, or transistor 202. Thus, each of transistors 401, 402, 403, 404, 405, 406, 407, 408, and 409 may be programmed as described above with reference to FIGS. 1A-3. Further, as described below with reference to FIG. 4B, individual transistors from among the array may be programmed and/or read at a given time based on the control of the separate word lines WL1, WL2, and WL3 and the separate bit lines BL1, BL2, and BL3.

FIG. 4B is a chart illustrating operating conditions of memory array 400 in accordance with embodiments of the present disclosure. FIG. 4B illustrates the operation of memory array 400 during the programming, and the reading, of the memory cell formed by transistor 405, for example.

To program transistor 405, transistor 405 must be driven in an on-state and a current conducted from the drain to the source. For example, supply voltage level VDD may be applied to WL2 to drive the gate-to-source voltage (Vgs) of transistor 405 above the gate-to-source threshold of transistor 405. In embodiments where transistors 401-409 are implemented in a 1.2 volt CMOS process, WL2 may be set to a VDD level of 1.2 volts for example. Further, a programming voltage VPP may be applied to BL2 to induce a programming current from the drain to the source of transistor 405.

During the programming of transistor 405, WL1 and WL3 may be held to zero volts to hold transistors 402 and 408 in an off-state, thus preventing the programing voltage VPP applied to BL2 from inducing an unwanted programming current through the non-selected transistors 402 and 408. Further, as described above with reference to FIG. 1A, the programming voltage VPP may be set at a level that is greater than the safe operating area (SOA) of the transistors 401-409, but less than the drain-to-source breakdown voltage (BVDSS) of transistors 401-409. For example, in an embodiment where transistors 401-409 are implemented with a 1.2 volt CMOS process, the safe operating area of transistors 401-409 may be between zero and 1.32 volts and the drain-to-source breakdown voltage (BVDSS) may be 8 volts. In such embodiments, VPP may be set to a voltage level less than the BVDSS of 8 volts. The application of the programming voltage VPP to BL2 may thus induce the desired programming current through transistor 405 while also avoiding damage to transistors 402 and 408 whose drains may also be coupled to BL2.

To read transistor 405, a VDD voltage may again be applied to WL2 to drive transistor 405 in an on-state. Meanwhile, WL1 and WL3 may be forced to zero to hold transistors 402 and 408 in an off-state, thereby preventing any drain current from transistors 402 and 408 from interfering with the measurement of the drain current from transistor 405. Moreover, BL1 and BL3 may be held to zero volts. As shown in FIG. 4B, a read voltage VDR may be applied to BL2. In some embodiments, the read voltage VDR may be a small voltage less than VDD. The read voltage VDR may be, for example, 100 millivolts. The drain current from transistor 405 induced by the VDR voltage may be read as an indicator as to whether transistor is in a non-programmed state (representing logic-0 for example) or a programmed state (representing logic-1 for example). For example, the drain current may be compared against a threshold. A drain current greater than the threshold may indicate that transistor 405 has not been programmed. Conversely, a drain current less than the threshold may indicate that transistor 405 has been programmed.

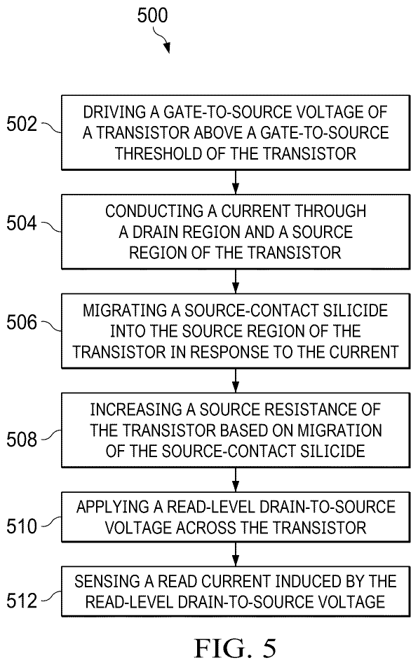

FIG. 5 illustrates an example method 500 of operating a one-time programmable (OTP) memory cell in accordance with embodiments of the present disclosure. Method 500 may be performed by and/or with any suitable mechanism, such as transistor 100, transistor 101, transistor 200, transistor 201, transistor 202, transistors 401-409, and/or any suitable combination thereof. Method 500 may be performed with fewer or more steps than shown in FIG. 5. Moreover, steps of method 500 may be omitted, repeated, performed in parallel, performed in a different order than shown in FIG. 5, or performed recursively. One or more steps of method 500, although shown in an order, may be performed at the same time or in a re-ordered manner. As one example, steps 506 and 508 may be performed at the same time as step 508.

Step 502 may include driving a gate-to-source voltage of a transistor above a gate-to-source threshold of the transistor. For example, as described above with reference to transistor 100 illustrated in FIG. 1A, the gate to source voltage (Vgs) of transistor 100 may be drive above its gate-to-source threshold to drive the transistor 100 in an on-state.

Step 504 may include conducting a current through a drain region and a source region of the transistor. For example, as described above with reference to transistor 100 illustrated in FIG. 1A, a programming voltage may applied from the drain to the source of transistor 100 to induce a programming current conducting from the drain region and to the source region of transistor 100. Some embodiments may include inducing the current through the drain region and the source region by applying a drain-to-source voltage that is greater than a safe-operating voltage of the transistor and less than a drain-to-source breakdown voltage (BVDSS) of the transistor.

Step 506 may include migrating a source-contact silicide into the source region of the transistor in response to the current. And step 508 may include increasing a source resistance of the transistor based on migration of the source-contact silicide. For example, as described above with reference to transistor 100 illustrated in FIG. 1A, a programming current conducted from the drain terminal to the source terminal of transistor 100 may cause an electron flux to flow out of the source contact formed by contact area 106a and into the source region formed by active area 102a in FIG. 1A. The electron flux may cause the source-contact silicide, located at the border between the source contact and the source region, to migrate into the source region and away from the source contact. The migration of the source-contact silicide may in turn reduce the electrical conductivity between the source contact and the underlying source region, thereby increasing the source resistance.

Step 510 may include applying a read-level drain-to-source voltage across the transistor. For example, as described above, with reference to FIG. 3, a read-level drain to source voltage of, for example, 100 millivolts, may be applied across the transistor to induce a drain current.

Step 512 may include sensing a read current induced by the read-level drain-to-source voltage. For example, as described above, with reference to FIG. 3 and also to FIG. 4B, the drain current induced by the application of the read voltage, such as a VDR of 100 millivolts for example, may be sensed as an indicator as to whether transistor is in a non-programmed state or a programmed state. In some embodiments, the drain current may be compared against a threshold. A drain current greater than the threshold may indicate that the transistor has not been programmed. Conversely, a drain current less than the threshold may indicate that source resistance of the transistor has been increased by programming.

Although examples have been described above, other modifications and variations may be made from this disclosure without departing from the spirit and scope of these examples. For example, although embodiments of various single-transistor memory cells are described above as being implemented with NMOS transistors, other embodiments of single-transistor memory cells may also be implemented with PMOS transistors according to the principles described herein. The above descriptions of various embodiments illustrate the principles of the invention. Numerous variations and modifications will become apparent to those skilled in the art based on the above disclosure. The following claims are intended to embrace all such variations and modifications.

What is claimed is:

1. A memory cell comprising:
a transistor including:
a gate;
a drain region coupled to a drain terminal by one or more drain contacts;
a source region coupled to a source terminal by a source contact, wherein a cumulative drain-contact area of the one or more drain contacts of the transistor is greater than a source-contact area of the transistor; and
a source-contact silicide located between the source contact and the source region, the source-contact silicide configured to migrate into the source region in response to a programming current conducted through the drain region and the source region.

2. The memory cell of claim 1, wherein the memory cell is a single-transistor memory cell.

3. The memory cell of claim 1, wherein the memory cell is a one-time programmable (OTP) memory cell.

4. The memory cell of claim 1, wherein the transistor is a single-transistor fuse.

5. The memory cell of claim 1, wherein the one or more drain contacts includes one or more drain-contact bars.

6. The memory cell of claim 1, wherein the transistor is a two-finger MOSFET.

7. The memory cell of claim 1, wherein the transistor is an n-type MOSFET.

8. The memory cell of claim 1, wherein the cumulative drain-contact area is greater than the source-contact area by a ratio of at least 10:1.

9. The memory cell of claim 1, wherein the source contact abuts an upper surface of the source region.

10. The memory cell of claim 1, wherein the source contact and the source-contact silicide extend into a recess in a surface of the source region.

11. A memory array comprising:
a plurality of memory cells arranged in one or more rows and one or more columns, wherein each of the plurality of memory cells comprises a transistor including:
a gate;
a drain region coupled to a drain terminal by one or more drain contacts;
a source region coupled to a source terminal by a source contact, wherein a cumulative drain-contact area of the one or more drain contacts of the transistor is greater than a source-contact area of the transistor; and
a source-contact silicide located between the source contact and the source region, the source-contact silicide configured to migrate in response to a programming current conducted through the drain region and the source region.

12. The memory array of claim 11, wherein each of the plurality of memory cells is a single-transistor memory cell.

13. The memory array of claim 11, wherein the transistor is an n-type MOSFET.

14. The memory array of claim 11, wherein the cumulative drain-contact area is greater than the source-contact area by a ratio of at least 10:1.

15. The memory array of claim 11, wherein the source contact abuts an upper surface of the source region.

16. The memory array of claim 11, wherein the source contact and the source-contact silicide extend into a recess in a surface of the source region.

17. A method for operating a one-time programmable (OTP) memory cell, comprising:
driving a gate-to-source voltage of a transistor above a gate-to-source threshold of the transistor;
conducting a current through a drain region and a source region of the transistor;
migrating a source-contact silicide into the source region of the transistor in response to the current; and
increasing a source resistance of the transistor based on migration of the source-contact silicide.

18. The method of claim 17, further comprising applying a drain-to-source voltage that is greater than a safe-operating voltage of the transistor and less than a drain-to-source breakdown voltage of the transistor.

19. The method of claim 17, further comprising:
applying a read-level drain-to-source voltage across the transistor; and
sensing a read current induced by the read-level drain-to-source voltage.

20. The method of claim 17, wherein a cumulative drain-contact area of one or more drain contacts of the transistor is greater than a source-contact area of the transistor by a ratio of at least 10:1.
